(19) United States
(12) Patent Application Publication
(10) Pub. No.: US 2014/0111274 A1
(43) Pub. Date: Apr. 24, 2014

(54) PROGRAMMABLE REVISION CELL ID SYSTEM AND METHOD

(71) Applicant: Conexant Systems, Inc., Irvine, CA (US)

(72) Inventor: Khosrow Golshan, Laguna Beach, CA (US)

(73) Assignee: Conexant Systems, Inc., Irvine, CA (US)

(21) Appl. No.: 14/062,840

(22) Filed: Oct. 24, 2013

Related U.S. Application Data
(60) Provisional application No. 61/718,120, filed on Oct. 24, 2012.

(51) Int. Cl. H01L 23/48; G06F 17/50

(52) U.S. Cl. CPC H01L 23/481; G06F 17/5077
USPC 327/564; 257/774; 716/126

(57) ABSTRACT

An integrated circuit comprising a plurality of metal programmable revision identification (MPRI) cells, wherein each MPRI cell further comprises a plurality of metal layers, a plurality of vias and an output.

### RELATED APPLICATIONS

This application claims benefit of U.S. Provisional Patent Application No. 61/718,120, filed Oct. 24, 2012, which is hereby incorporated by reference for all purposes as if set forth herein in its entirety.

### TECHNICAL FIELD

The present disclosure relates generaly to coding of revision identification data in an integrated circuit, and more specifically to a programmable revision cell identification system and method for coding revision identification data in an integrated circuit.

### BACKGROUND OF THE INVENTION

During the design process, integrated circuits are revised a number of times. Likewise, after a first integrated circuit product is made, subsequent modifications of the integrated circuit may be implemented. In order to keep track of the version of an integrated circuit, a sequence number is typically provided. However, existing systems and methods for keeping track of the sequence number typically requires active devices, which can fail during manufacture or testing, and which reduces the overall yield for a manufacturing batch or which can lead to errors in subsequent use of the integrated circuit.

### SUMMARY OF THE INVENTION

An integrated circuit is provided that includes a plurality of metal programmable revision identification (MPRI) cells. Each MPRI cell further comprises a plurality of metal layers, a plurality of vias and an output.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a first metal interconnect that is used for the connection from the output of either TI_LOW or TI_HIGH to the output of the MPRI cell through the metal ladder, in accordance with an exemplary embodiment of the present disclosure;

FIG. 2 is a diagram showing modification of a polarity of the output logic one to logic zero using a routing change in metal layer two, in accordance with an exemplary embodiment of the present disclosure;

FIG. 3 is a diagram of a system for providing a revision ID using MPRI cells in accordance with an exemplary embodiment of the present disclosure;

FIG. 4 is a diagram of an algorithm for modifying a circuit to implement an MPRI cell modification in accordance with an exemplary embodiment of the present disclosure;

FIG. 5 is a diagram of MPRI cell base layers (Polysilicon, Metal one and VIA) shown with TI_HIGH and T_LOW in accordance with an exemplary embodiment of the present disclosure;

FIG. 6 is a diagram of an MPRI full layout in accordance with an exemplary embodiment of the present disclosure;

FIG. 7 is a diagram showing connection of a TI_HIGH output to MPRI output before a routing change in accordance with an exemplary embodiment of the present disclosure; and

FIG. 8 is a diagram showing connection of a TI_LOW output to MPRI output after a routing change in accordance with an exemplary embodiment of the present disclosure.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

Conventionally, the revision ID of an integrated circuit is implemented as bits that are tied to either VDD (supply) or VSS (ground) at any arbitrary layer (and most likely, lower level metals) of an integrated circuit, and includes registers, buffers or inverters that are dedicated for the purpose of identifying the integrated circuit version.

Often, an additional metal layer can be consumed by the revision ID when actual design changes are made on a different metal layer than where the revision ID was originally connected. For example, an additional metal layer can be consumed if the chip requires a logic fix on metal layer one, and the next revision ID bit needs to be tied to VSS (ground) on metal layer two. This change will require two additional metal mask layer changes on top of the changes that were made on the different metal layers. If the revision ID could be changed in the metal layer using the same metal layer that was used for the actual design, modification to metal layers one and two would not be necessary.

In addition, there is an engineering cost to the layout task that is incurred in order to minimize the number of layers used to implement a change in the device revision ID as well. Therefore, significant cost savings can be attained if the extra of mask layers can be eliminated, in addition to the engineering time required to implement ID bit changes.

The present disclosure utilizes an integrated circuit cell structure, or Metal Programmable Revision ID (MPRI), that allows revision ID bit modifications to be constructed by using mask layers where required logic changes are made. The MPRI cell comprises metal interconnect structures that are dependent upon the total number of metal layers that are used in an integrated circuit.

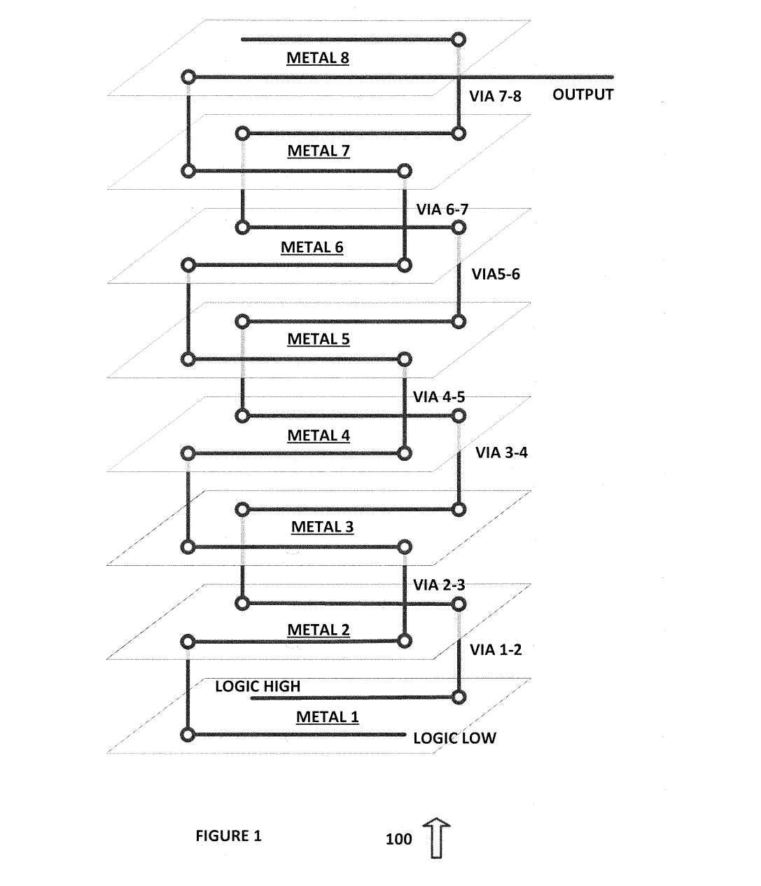

FIG. 1 is a diagram 100 of a first metal interconnect that is used for the connection from the output of either TI_LOW or TI_HIGH to the output of the MPRI cell through the metal ladder, in accordance with an exemplary embodiment of the present disclosure. The MPRI cell contains a TI_HIGH circuit and a TI_LOW circuit, which are connected to VDD and VSS through PFET and NFET transistors, with output logic levels of one and zero, respectively.

In one exemplary embodiment, two types of MPRI cells are provided. One provides logic zero at the output and the second provides logic one at the output, and they are used as a default in an integrated circuit to form various revision ID configurations. Both types of MPRI cell are footprint- and transistor-compatible, allowing them to be interchanged without using low level masks (such as diffusion, polysilicon or via masks).

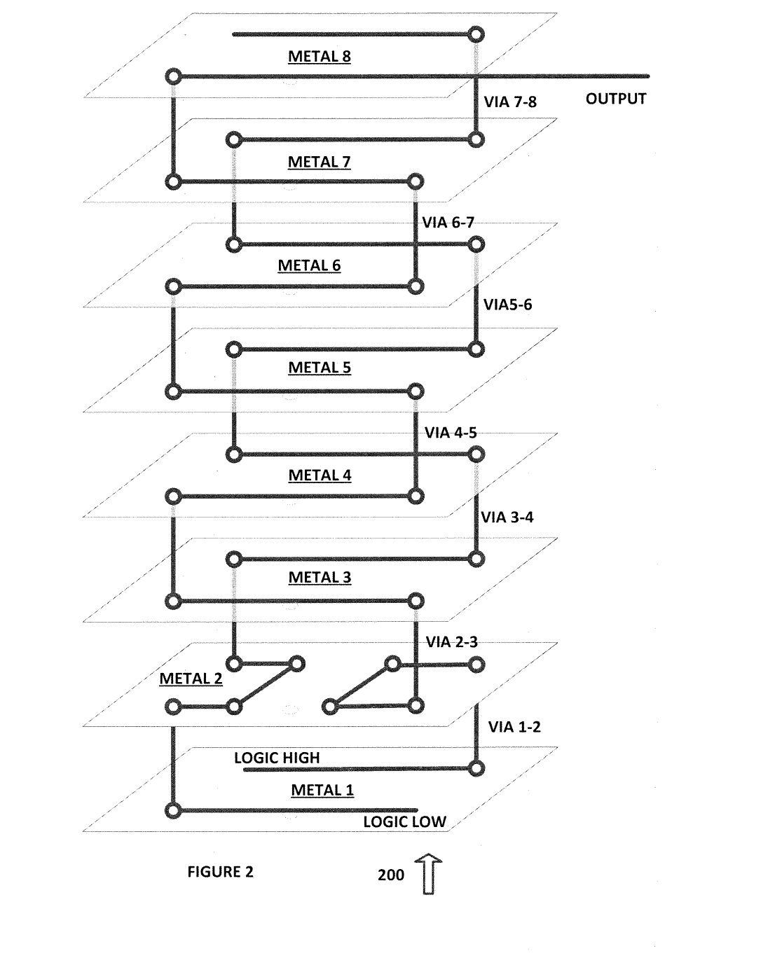

FIG. 2 is a diagram 200 showing modification of a polarity of the output logic one to logic zero using a routing change in metal layer two, in accordance with an exemplary embodiment of the present disclosure. MPRI can be implemented using the conventional “standard cells” layout technique, in which rows are the same height as the other cells in the library, so that abutment to them is possible. In this exemplary embodiment, MPRI includes TI_HIGH and TI_LOW logic which provides logic one or logic zero, as shown in FIG. 5. All metals are used in the ladder structure as shown in FIG. 1, to connect the output TI_HI or TI_LOW to the output of the MPRI cell.

Since MPRI is considered a standard cell, during the automatic placement and routing of the cell, any gaps between the cell and the other cells can be filled with “standard metal filler” cells. These standard metal filler cells contain geometries which extend certain layers across the gaps, such as power straps and well implants.

The gaps between the standard metal filler cells that are caused by the inefficiency of the routing tool used by the layout designer can be filled automatically in order to comply with Design Rule Check (DRC) requirements.

Although a routing configuration change on metal layer two is shown in diagram 200, other suitable routing configuration changes can also or alternatively be used to implement the change in the output of the MPRI cell, such as a routing configuration change on metal layer one or metal layers three through eight. Likewise, routing configuration changes on multiple metal layers can also or alternatively be used, such as routing configuration changes on two of the metal layers to generate a logic one output, routing configuration changes on three of the metal layers to generate a logic zero output, routing configuration changes on an even number of the metal layers to generate a logic one output, routing configuration changes on an odd number of the metal layers to generate a logic zero output, or other suitable routing configuration changes.

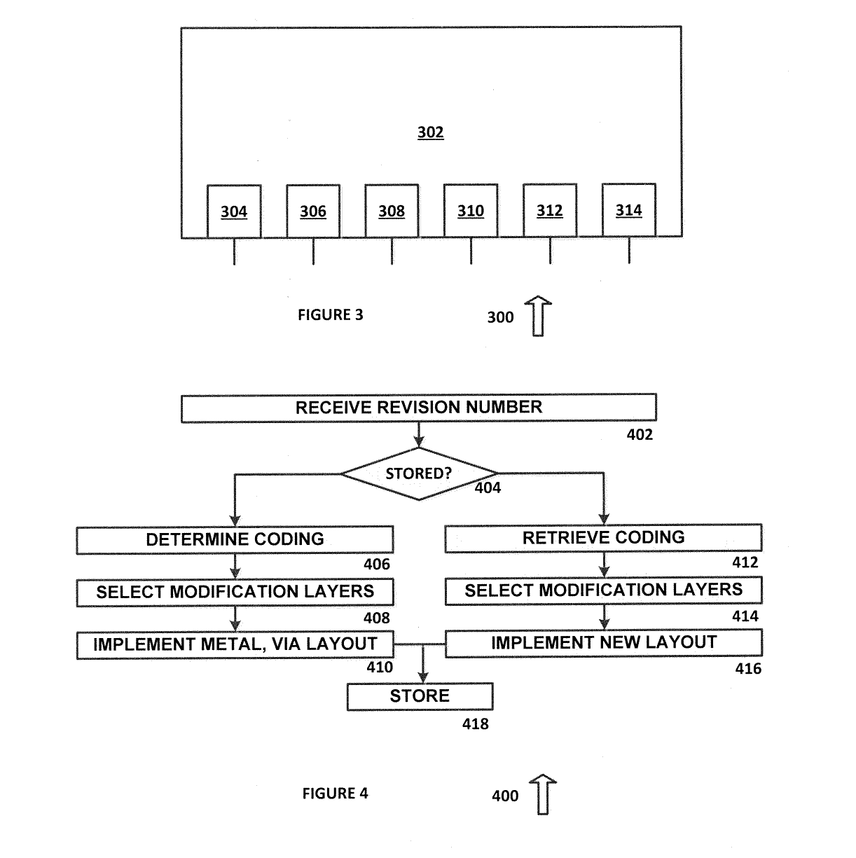

FIG. 3 is a diagram of a system 300 for providing a revision ID using MPRI cells in accordance with an exemplary embodiment of the present disclosure. System 300 includes integrated circuit 302 and MPRI cells 304 through 314, each of which can provide a logic zero or logic one output. When a revision is made to the design of integrated circuit 302, the output of MPRI cells 304 through 314 is modified to increment the number of the revision. For example, an initial revision number of “0 0 0 0 0 0” may be assigned for the first initial design of integrated circuit 302, such as using a first cell design for each of MPRI cells 304 through 314 that generates an out of logic zero. When a change or plurality of changes are made to the design of integrated circuit 302, the revision number of MPRI cells 304 through 314 can be changed to “0 0 0 0 0 1,” such as by replacing the design of MPRI cell 314 with a second cell design that generates an output of logic one. In this manner, the revision ID of system 300 can be modified using a standard cell design and without requiring additional metal layers, complex revision ID re-design or other complex design and/or circuit analysis to be performed.

FIG. 4 is a diagram of an algorithm 400 for modifying a circuit to implement an MPRI cell modification in accordance with an exemplary embodiment of the present disclosure. Algorithm 400 can be implemented in hardware or a suitable combination of hardware and software, and can be one or more algorithms operating on a general purpose processor.

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications or on two or more processors, or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections.

Algorithm 400 begins at 402, where a revision number is received. In one exemplary embodiment, a revision number of a prior revision can be extracted from a data memory device, such as when an integrated circuit design is loaded into a system memory, by extracting a stored revision from a data memory device, or in other suitable manners. The algorithm then proceeds to 404.

At 404, it is determined whether an integrated circuit design has been stored. In one exemplary embodiment, when an integrated circuit design is stored for the first time, the algorithm proceeds to 406. Alternatively, if the integrated circuit design has previously been stored as a revision in a non-transient electronic data memory device, such as random access memory, read-only memory, silicon memory devices, magnetic memory devices, optical memory devices or other suitable data memory devices, the algorithm proceeds to 412.

At 406, a starting revision number tracking circuit design can be determined, such as by generating a plurality of MPRI cells that are arranged in a serial layout and which generate a logical identifier of 0 0 0 0 0, or other suitable identifiers that represent that the integrated circuit design is the first or base revision of the circuit. The algorithm then proceeds to 408.

At 408, one or more modification layers are selected. In one exemplary embodiment, each MPRI cell can be implemented at a plurality of layers based on one or more design rules, such as a layout versus schematic rule, an XOR rule, an electrical rule, an antenna rule, a width rule, a spacing rule, an enclosure rule, an ESD rule, an I/O rule or other suitable design rules. For example, design rules can be checked for modification of one or more layers, and layers can be selected as a function of a ranking algorithm associated with the design rules, a predetermined priority associated with the design rules or each layer or other suitable procedures can also or alternatively be used. The algorithm then proceeds to 410.

At 410, a new metal and via layout is implement to create MPRI cells having the revision number coding. In one exemplary embodiment, the new metal and via layout can be generated without additional input from a designer. In another exemplary embodiment, the new metal and via layout can be generated after review and approval by a designer, or in other suitable manners. The algorithm then proceeds to 418, where the design is stored.

At 412, the revision number coding is retrieved and a new revision number coding is determined. In one exemplary embodiment, the revision number can be a binary number and the new revision number coding can implement an increment in the revision number. For example, if the existing revision number is “0 1 1 1 1 1,” for a six MPRI cell revision number device, then the new revision number coding can be “1 0 0 0 0 0” if the next revision number is incremented by one. The algorithm then proceeds to 414.

At 414, one or more modification layers are selected. In one exemplary embodiment, a change to a single MPRI cell can be implemented at a layer based on one or more design rules, such as a layout versus schematic rule, an XOR rule, an electrical rule, an antenna rule, a width rule, a spacing rule, an enclosure rule, an ESD rule, an I/O rule or other suitable design rules. For example, design rules can be checked for modification of one or more layers, and layers can be selected as a function of a ranking algorithm associated with the design rules, a predetermined priority associated with the design rules or each layer or other suitable procedures can also or alternatively be used. The algorithm then proceeds to 416.

At 416, a new metal and via layout is implement to create MPRI cells having the new revision number coding. In one exemplary embodiment, the new metal and via layout can be generated without additional input from a designer. In another exemplary embodiment, the new metal and via layout can be generated after review and approval by a designer, or in other suitable manners. The algorithm then proceeds to 418.

In operation, algorithm 400 allows revision number coding to be automatically implemented without little or no designer input, by using standardized MPRI cells and automatically implemented metal and via layout selection and implementation. Algorithm 400 thus reduces or eliminates the need for designer input to implement a new revision number coding for a revision to an integrated circuit design.

FIG. 5 is a diagram 500 of MPRI cell base layers (Polysilicon, Metal one and VIA) shown with TI_HIGH and T_LOW in accordance with an exemplary embodiment of the present disclosure. Diagram 500 provides an example of a standard MPRI cell, such as one that generates a logic zero or logic one.

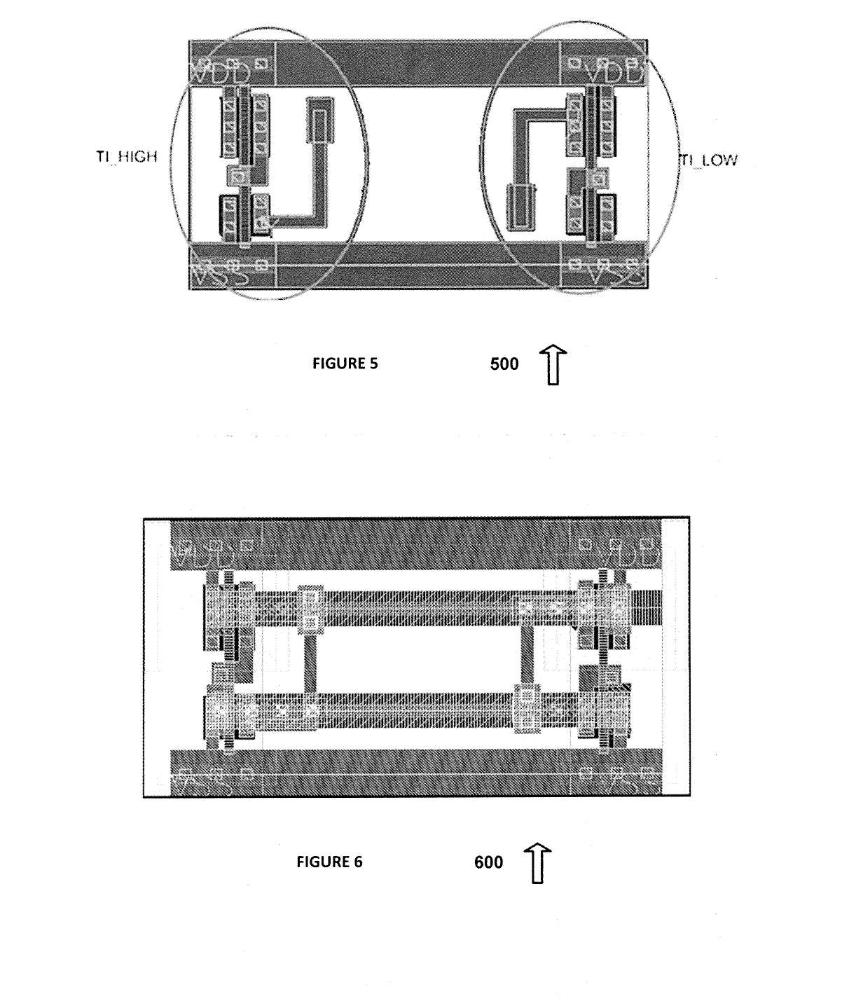

FIG. 6 is a diagram 600 of an MPRI full layout in accordance with an exemplary embodiment of the present disclosure. Diagram 600 provides an example of a standard MPRI cell, such as one that generates a logic zero or logic one.

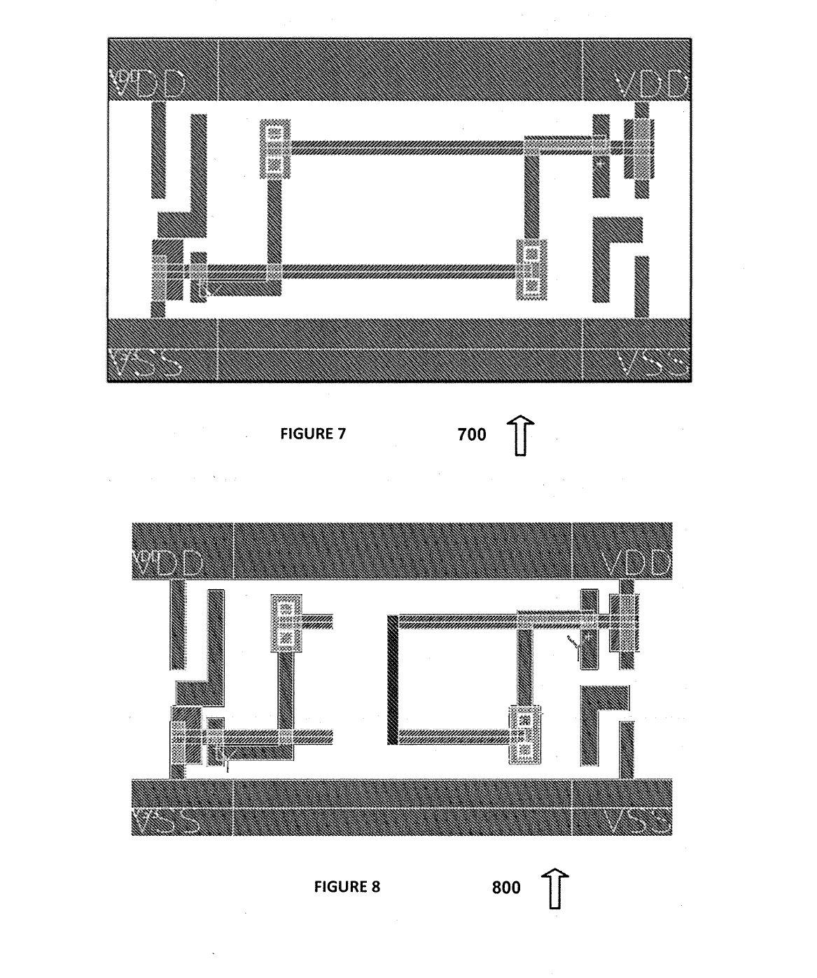

FIG. 7 is a diagram 700 showing connection of a TI_HIGH output to MPRI output before a routing change in accordance with an exemplary embodiment of the present disclosure. Diagram 700 provides an example of a standard MPRI cell, such as one that generates a logic zero or logic one.

FIG. 8 is a diagram 800 showing connection of a TI_LOW output to MPRI output after a routing change in accordance with an exemplary embodiment of the present disclosure. Diagram 800 provides an example of a standard MPRI cell, such as one that generates a logic zero or logic one.

The present disclosure can be utilized with all metal layers and independent of other metal layers. In this manner, the selection and modification of MPRI cells can be programmed using only the metal layers that are used to modify the logic.

The present disclosure provides a number of advantages when compared to conventional methodologies. One exemplary advantage is to reduce additional metal mask cost that may be required to implement revision ID changes and to eliminate the need for default register changes, buffers and inverters. Another exemplary advantage is to reduce additional engineering labor costs for the implementation of revision ID changes and associated default register changes, buffer and inverter. Another exemplary advantage is reduction of costs and complexity of implementation from metal only implementation. Another exemplary advantage is that single metal layer or via layer changes can be made at any suitable metal layer. Another exemplary advantage is that flexible modification capability is provided. Another exemplary advantage is the small footprint size that is required, which saves area required for the integrated circuit. Another exemplary advantage is that excellent reliability is provided due to metal only implementation. Another exemplary advantage is the use of pair cells (logic one and logic zero), which eliminates the need for inverters and buffers. Another exemplary advantage is that the MPRI cells fit in a standard cell format which allows them to be used by place and route tools. Another exemplary advantage is the simplification of layout changes with regard to revision ID. Another exemplary advantage is the implementation in existing design through an Engineering Change Order (ECO) process or for new chip designs.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. An integrated circuit comprising:
a plurality of metal programmable revision identification (MPRI) cells, wherein each MPRI cell further comprises:
a plurality of metal layers;
a plurality of vias; and
an output.

2. The integrated circuit of claim 1 wherein a first MPRI cell of the plurality of MPRI cells has a different configuration of vias than a second MPRI cell of the plurality of MPRI cells.

3. The integrated circuit of claim 2 wherein a third MPRI cell of the plurality of MPRI cells has an identical configuration of vias as the first MPRI cell.

4. The integrated circuit of claim 1 wherein a first MPRI cell of the plurality of MPRI cells has a different configuration of metal layers than a second MPRI cell of the plurality of MPRI cells.

5. The integrated circuit of claim 4 wherein a third MPRI cell of the plurality of MPRI cells has an identical configuration of metal layers as the first MPRI cell.

6. The integrated circuit of claim 1 wherein a first MPRI cell of the plurality of MPRI cells has a different configuration of vias than a second MPRI cell of the plurality of MPRI cells, and the first MPRI cell of the plurality of MPRI cells has a different configuration of metal layers than the second MPRI cell of the plurality of MPRI cells.

7. The integrated circuit of claim 1 wherein a first MPRI cell of the plurality of MPRI cells has a different configuration of vias than a second MPRI cell of the plurality of MPRI cells, the first MPRI cell of the plurality of MPRI cells has a different configuration of metal layers than the second MPRI cell of the plurality of MPRI cells, a third MPRI cell of the plurality of MPRI cells has an identical configuration of vias as the first MPRI cell of the plurality of MPRI cells, and the third MPRI cell of the plurality of MPRI cells has an identical configuration of metal layers as the third MPRI cell of the plurality of MPRI cells.

8. A method for identifying an integrated circuit revision, comprising:
generating a first cell output using a first configuration of metal layers and vias; and
generating a second cell output using a second configuration of metal layers and vias;
wherein the first configuration of metal layers and vias is different from the second configuration of metal layers and vias.

9. The method of claim 8 wherein the first configuration of metal layers and vias is different from the second configuration of metal layers and vias by two metal layer connections.

10. The method of claim 8 wherein the first configuration of metal layers and vias is different from the second configuration of metal layers and vias by two metal layer connections on an even number of metal layers.

11. The method of claim 8 wherein the first configuration of metal layers and vias is different from the second configuration of metal layers and vias by two metal layer connections on an odd number of metal layers.

12. The method of claim 8 further comprising:
receiving a revision change control; and
revising the first cell output using a third configuration of metal layers and vias.

13. The method of claim 12 wherein the third configuration of metal layers and vias is identical to the second configuration of metal layers and vias.

14. The method of claim 8 further comprising storing the first cell output and the second cell output in a non-transient data memory.

15. The method of claim 14 further comprising:
receiving a revision change control;
retrieving the first cell output and the second cell output from the non-transient data memory;
revising the first cell output using a third configuration of metal layers and vias; and
storing the revised first cell output and the second cell output in a non-transient data memory.

16. In an integrated circuit having a plurality of metal programmable revision identification (MPRI) cells, wherein each MPRI cell includes a plurality of metal layers, a plurality of vias and an output, and the integrated circuit further includes a first MPRI cell of the plurality of MPRI cells that has a different configuration of vias than a second MPRI cell of the plurality of MPRI cells, the first MPRI cell of the plurality of MPRI cells has a different configuration of metal layers than the second MPRI cell of the plurality of MPRI cells, a third MPRI cell of the plurality of MPRI cells has an identical configuration of vias as the first MPRI cell of the plurality of MPRI cells, and the third MPRI cell of the plurality of MPRI cells has an identical configuration of metal layers as the third MPRI cell of the plurality of MPRI cells, a method for identifying an integrated circuit revision, comprising:
generating the first MPRI cell output using a first configuration of metal layers and vias;
generating the second MPRI cell output using a second configuration of metal layers and vias;
generating the third MPRI cell output using a third configuration of metal layers and vias;
storing the first MPRI cell output, the second MPRI cell output and the third MPRI cell output in a non-transient data memory device;
receiving a revision change control;
retrieving the first MPRI cell output, the second MPRI cell output and the third MPRI cell output from the non-transient data memory device;
revising the first MPRI cell output using a fourth configuration of metal layers and vias; and
storing the revised first MPRI cell output, the second MPRI cell output and the third MPRI cell output in the non-transient data memory device.
